(19) United States
(12) Patent Application Publication
(10) Pub. No.: US 2018/0122833 A1
(43) Pub. Date: May 3, 2018

(54) THIN FILM TRANSISTOR SUBSTRATE HAVING BI-LAYER OXIDE SEMICONDUCTOR

(71) Applicant: LG Display Co. , Ltd., Seoul (KR)

(72) Inventors: Sohyung LEE, Goyang-si (KR); Sungki KIM, Seoul (KR); Youngjin YI, Paju-si (KR); Mincheol KIM, Paju-si (KR); Jeongsuk YANG, Asan-si (KR); Seoyeon IM, Jeju-si (KR)

(73) Assignee: LG Display Co. , Ltd., Seoul (KR)

(21) Appl. No.: 15/798,776

(22) Filed: Oct. 31, 2017

(30) Foreign Application Priority Data
Oct. 31, 2016 (KR) 10-2016-0144008
May 31, 2017 (KR) 10-2017-0067967

(51) Int. Cl. H01L 27/12; H01L 29/786; H01L 29/26; H01L 29/24

(52) U.S. Cl. CPC H01L 27/1225; H01L 29/24; H01L 29/26; H01L 29/7869

(57) ABSTRACT

The present disclosure relates to a thin film transistor substrate having a bi-layer oxide semiconductor. The present disclosure provides a thin film transistor substrate comprising: a substrate; and an oxide semiconductor layer on the substrate, wherein the oxide semiconductor layer includes: a first oxide semiconductor layer having indium, gallium and zinc; and a second oxide semiconductor layer stacked on the first oxide semiconductor layer having the indium, gallium and zinc, wherein any one layer of the first and the second oxide semiconductor layers has a first composition ratio of the indium, gallium and zinc of 1:1:1; and wherein other layer has a second composition ratio of the indium, gallium and zinc in which the indium ratio is higher than the zinc ratio.

### CROSS-REFERENCE TO RELATED APPLICATION

This application claims priority to Republic of Korea Patent Application Nos. 10-2016-0144008 and 10-2017-0067967, respectively filed on Oct. 31, 2016 and May 31, 2017, which are hereby incorporated by reference in their entirety.

### BACKGROUND

### Field of the Disclosure

The present disclosure relates to a display device, and more particularly, to a thin film transistor substrate having a bi-layer oxide semiconductor. Although the present disclosure is suitable for a wide scope of applications, it is particularly suitable for displaying the ultra-high definition (UHD) or higher resolution on the display device.

### Description of the Background

As the information society is developed, requirements of displays for representing information are increasing. Accordingly, various flat panel displays (or ‘FPD’) are developed for overcoming many drawbacks of the cathode ray tube (or ‘CRT’) such as heavy weight and bulkiness. The flat panel display devices include liquid crystal display devices (or ‘LCD’), field emission displays (or ‘FED’), plasma display panels (or ‘FDP’), organic light emitting display devices (or ‘OLED’) and electrophoresis display devices (or ‘ED’).

The display panel of the flat panel display may include a thin film transistor substrate having a thin film transistor allocated in each pixel region arrayed in a matrix manner. For example, the liquid crystal display device represents video data by controlling the light transitivity of the liquid crystal layer using the electric fields. The organic light emitting diode display represents the video image by forming an organic light emitting diode at each of a plurality of the pixel areas arrayed in a matrix manner.

FIG. 1 is a plan view illustrating a thin film transistor substrate having an oxide semiconductor layer of the fringe field type liquid crystal display according to the related art. FIG. 2 is a cross sectional view illustrating the thin film transistor substrate along cutting line I-I′ in FIG. 1.

The thin film transistor substrate having a metal oxide semiconductor layer shown in FIGS. 1 and 2 comprises a gate line GL and a data line DL crossing each other with a gate insulating layer GI therebetween on a lower substrate SUB, and a thin film transistor T formed at each crossing portion. By the crossing structure of the gate line GL and the data line DL, a pixel region is defined.

The thin film transistor T comprises a gate electrode G branched (or ‘extruded’) from the gate line GL, a source electrode S branched from the data line DL, a drain electrode D facing the source electrode S and connecting to the pixel electrode PXL via a pixel contact hole PH, and a semiconductor layer A overlapping the gate electrode G on the gate insulating layer GI for forming a channel between the source electrode S and the drain electrode D.

The semiconductor layer A made of an oxide semiconductor material has an advantage for a large area thin film transistor substrate having a large charging capacitance, due to the high electron mobility of the oxide semiconductor layer. However, the thin film transistor having the oxide semiconductor material needs an etch stopper ES for protecting the upper surface of the semiconductor layer from the etching material for ensuring the stability and the characteristics of the thin film transistor. More particularly, it is required to have an etch stopper ES for protecting the semiconductor layer A from the etchant used for forming the source electrode S and the drain electrode D there-between.

At one end of the gate line GL, a gate pad GP is formed for receiving the gate signal. The gate pad GP is connected to a gate pad intermediate terminal IGT through a first gate pad contact hole GH1 penetrating the gate insulating layer GI. The gate pad intermediate terminal IGT is connected to a gate pad terminal GPT through the second gate pad contact hole GH2 penetrating into the first passivation layer PA1 and the second passivation layer PA2. Further, at one end of the data line DL, a data pad DP is formed for receiving the pixel signal. The data pad DP is connected to a data pad terminal DPT through the data pad contact hole DPH penetrating the first passivation layer PA1 and the second passivation layer PA2.

In the pixel region, a pixel electrode PXL and a common electrode COM are formed with the second passivation layer PA2 there-between, to form a fringe electric field. The common electrode COM is connected to the common line CL disposed in parallel with the gate line GL. The common electrode COM is supplied with a reference voltage (or “common voltage”) via the common line CL.

The common electrode COM and the pixel electrode PXL can have various shapes and positions according to the design purpose and environment. While the common electrode COM is supplied with a reference voltage having constant value, the pixel electrode PXL is supplied with a data voltage varying timely according to the video data. Therefore, between the data line DL and the pixel electrode PXL, a parasitic capacitance may be formed. Due to the parasitic capacitance, the video quality of the display can be degraded. Therefore, the common electrode COM has to be formed at first and then the pixel electrode PXL is formed on the topmost layer.

In other words, on the first passivation layer PA1 covering the data line DL and the thin film transistor T, a planarization layer PAC formed by thickly depositing an organic material having a low permittivity. Then, the common electrode COM is formed. And then, after depositing the second passivation layer PA2 to cover the common electrode COM, the pixel electrode PXL overlapping the common electrode is formed on the second passivation layer PA2. In this structure, the pixel electrode PXL is positioned far from the data line DL by the first passivation layer PA1, the planarization layer PAC and the second passivation layer PA2, so that the parasitic capacitance can be reduced between the data line DL and the pixel electrode PXL.

The common electrode COM is formed to a rectangular shape corresponding to the pixel region. The pixel electrode PXL is formed to have a plurality of segments. Especially, the pixel electrode PXL vertically overlaps the common electrode COM with the second passivation layer PA2 there-between. Between the pixel electrode PXL and the common electrode COM, the fringe electric field is formed. By this fringe electric field, the liquid crystal molecules arrayed in a plane direction between the thin film transistor substrate and the color filter substrate may be rotated according to the dielectric anisotropy of the liquid crystal molecules. According to the rotation degree of the liquid crystal molecules, the light transmittance ratio of the pixel region may be changed so as to represent desired gray scale.

For another example of the flat panel display, there is an electro-luminescence display. The electro-luminescence display device is categorized in the inorganic light emitting diode display device and the organic light emitting diode display device according to the luminescence material. As a self-emitting display device, the electroluminescence display device has advantages in that the response speed is very fast, the brightness is very high and the view angle is large. The organic light emitting diode display (or OLED) using the organic light emitting diode can be categorized in a passive matrix type organic light emitting diode display (or PMOLED) and an active matrix type organic light emitting diode display (or AMOLED).

FIG. 3 is a plan view illustrating the structure of a pixel in an active matrix organic light emitting diode display according to the relate art. FIG. 4 is a cross sectional view illustrating the structure of the active matrix organic light emitting diode display along cutting line II-II′ in FIG. 3.

Referring to FIGS. 3 and 4, the active matrix organic light emitting diode display comprises a switching thin film transistor ST, a driving thin film transistor DT connected to the switching thin film transistor ST, and an organic light emitting diode OLE connected to the driving thin film transistor DT.

The switching thin film transistor ST is disposed where the scan line SL and the data line DL are crossing each other. The switching thin film transistor ST selects the pixel. The switching thin film transistor ST includes a gate electrode SG branched from the scan line SL, a semiconductor layer SA, a source electrode SS and a drain electrode SD. The driving thin film transistor DT operates the organic light emitting diode OLE of the pixel selected by the switching thin film transistor ST.

The driving thin film transistor DT includes a gate electrode DG connected to the drain electrode SD of the switching thin film transistor ST, a semiconductor layer DA, a source electrode DS connected to a driving current line VDD, and a drain electrode DD. The drain electrode DD of the driving thin film transistor DT is connected to an anode electrode ANO of the organic light emitting diode OLE. Between the anode electrode ANO and the cathode electrode CAT, the organic light emitting layer OL is disposed. The cathode electrode CAT is supplied with the low level voltage or the ground level voltage.

In detail, referring to FIG. 4, the gate electrodes SG and DG of the switching thin film transistor ST and the driving thin film transistor DT are formed on the substrate SUB. On the gate electrodes SG and DG, the gate insulating layer GI is deposited. On the gate insulating layer GI, the semiconductor layers SA and DA are disposed and vertically overlapping the gate electrodes SG and DG, respectively. On the semiconductor layers SA and DA, the source electrodes SS and DS and the drain electrodes SD and DD are formed and facing each other, respectively. The drain electrode SD of the switching thin film transistor ST is connected to the gate electrode DG of the driving thin film transistor DT via the gate contact hole GH formed at the gate insulating layer GI. The passivation layer PAS is deposited on the whole surface of the substrate SUB having the switching thin film transistor ST and the driving thin film transistor DT.

A color filter CF may be formed at a region where the anode electrode ANO to be formed later. The color filter CF needs to have the largest area within the pixel area. For example, the color filter CF vertically overlaps the data line DL, the driving current line VDD and the scan line SL. The upper surface of the substrate having these thin film transistors ST and DT is not in even and/or smooth conditions, but in uneven and/or rugged conditions having step height difference. In order to get optimum light emitting efficiency, the organic light emitting layer OL needs to be deposited on an even or planar surface. So, to make the upper surface in planar and even conditions, the over coat layer OC is deposited on the entire surface of the substrate OC.

Then, on the over coat layer OC, the anode electrode ANO of the organic light emitting diode OLE is formed. Here, the anode electrode ANO is connected to the drain electrode DD of the driving thin film transistor DT through the pixel contact hole PH penetrating into the over coat layer OC and the passivation layer PAS.

On the substrate SUB having the anode electrode ANO, a bank BANK is formed over the area having the switching thin film transistor ST, the driving thin film transistor DT and the various lines DL, SL and VDD, for defining the light emitting area. The exposed portion of the anode electrode ANO by the bank BANK becomes the light emitting area. On the organic light emitting layer OL, a cathode electrode CAT is sequentially deposited.

For the case that the organic light emitting layer OL is made of the organic material radiating white lights, the color data can be represented by the color filter CF disposed under the organic light emitting layer OL. The organic light emitting diode display as shown in FIG. 4 is the bottom emission type organic light emitting diode display in which the lights are radiated to the substrate SUB from the organic light emitting layer OL.

By applying the thin film transistor as described above, a high quality active matrix flat panel display can be acquired. Especially, to ensure the superior performance of the thin film transistor, the thin film transistor can include a metal oxide semiconductor material.

For the case that the thin film transistor substrate includes the oxide semiconductor material, the specific technology is required for ensuring the superior semiconductor characteristics. For example, making the channel have a shorter length, due to the short channel effect, the thin film transistor can be applied to the higher speed operation. However, when the channel length is too short, the threshold voltage of the thin film transistor can be lowered so that it becomes difficult to drive the thin film transistor.

In order to ensure the superior characteristics of the short channel thin film transistor and to maintain the proper threshold voltage, the oxide semiconductor layer can be formed to have a thickness as thin as possible. The display has a vast number of thin film transistors over the large surface area. Since it is difficult to have a thin thickness semiconductor layer over a large area, the manufacturing yields (or productivity) can be very poor.

Alternatively, the oxide may be doped into the gate insulating layer and/or the passivation layer stacked on and/or under the oxide semiconductor layer. In this case, due to the doped oxygen particles, the threshold voltage cannot be controlled when the thin film transistor is operated for a long time. As a result, due to the positive bias thermal stress, the thin film transistor can be degraded easily. Therefore, a new technology for ensuring stable high characteristics of the oxide semiconductor material is required for developing a thin film transistor substrate of the large area display.

### SUMMARY

Accordingly, in order to overcome the above mentioned drawbacks, the present disclosure is to provide an ultra-high definition (UHD) flat panel display over UHD resolution. In addition, the present disclosure is to provide a thin film transistor substrate having short channel length favorable for the high speed operation and with stable threshold voltage for a long time. Further, the present disclosure is to provide a thin film transistor substrate having the superior switching characteristics for large area ultra high density flat panel display.

In order to accomplish the above features and advantages, one aspect of the present disclosure provides a thin film transistor substrate comprising: a substrate; and an oxide semiconductor layer on the substrate, wherein the oxide semiconductor layer includes: a first oxide semiconductor layer having indium, gallium and zinc; and a second oxide semiconductor layer stacked on the first oxide semiconductor layer having the indium, gallium and zinc, wherein any one layer of the first and the second oxide semiconductor layers has a first composition ratio of the indium, gallium and zinc of 1:1:1; and wherein other layer has a second composition ratio of the indium, gallium and zinc in which the indium ratio is higher than the zinc ratio.

In another aspect of the present disclosure, a thin film transistor substrate for a display device comprises a substrate; a first oxide semiconductor layer on or over the substrate; a second oxide semiconductor layer on the first oxide semiconductor layer, wherein the first and second oxide semiconductor layers include indium, gallium and zinc and have different composition ratios in indium, gallium and zinc, the first oxide semiconductor layer has a higher resistivity than the second oxide semiconductor layer, and a threshold voltage of the display device changes less than 1.0 voltage when a channel length is reduced.

In a further aspect of the present disclosure, A thin film transistor substrate for a display device comprises a substrate; a first oxide semiconductor layer on the substrate; a second oxide semiconductor layer on the first oxide semiconductor layer, wherein the first and second oxide semiconductor layers include indium, gallium and zinc and have different composition ratios in indium, gallium and zinc, the first oxide semiconductor layer a lower resistivity than the second oxide semiconductor layer, and a threshold voltage of the display device changes less than 1.0 voltage when a channel length is reduced; a gate insulating layer on the second oxide semiconductor layer; a gate electrode on the gate insulating layer and vertically overlapping a middle portion of the second oxide semiconductor layer; an intermediate insulating layer on the gate electrode; and a source electrode and a drain electrode on the intermediate insulating layer, wherein the source electrode contacts a first portion of the second oxide semiconductor layer through a source contact hole, and the drain electrode contacts a second portion of the second oxide semiconductor layer through a drain contact hole.

In some aspects, the second composition ratio of the indium, gallium and zinc has a condition in which the zinc ratio to the gallium ratio is equal to or higher than 0 (zero), and lower than 0.5.

In some aspects, the second composition ratio of the indium, gallium and zinc has a condition in which the gallium ratio to the indium ratio is higher than 1.

In some aspects, the second composition ratio of the indium, gallium and zinc has a condition selected any one from 1:2:0 to 1:2:0.9.

In some aspects, the thin film transistor substrate further comprises: a gate electrode overlapped with the oxide semiconductor layer with a gate insulating layer there-between under the first oxide semiconductor layer; a source electrode contacting one upper surface of the first oxide semiconductor layer; and a drain electrode contacting another upper surface of the first oxide semiconductor layer, wherein the first oxide semiconductor layer has the first composition ratio and the second oxide semiconductor layer has the second composition ratio.

In some aspects, the second oxide semiconductor layer has a smaller area than the first oxide semiconductor layer, and is disposed on a middle portion of the first oxide semiconductor layer.

In some aspects, the source electrode further contacts one upper surface of the second oxide semiconductor layer; and the drain electrode further contacts another upper surface of the second oxide semiconductor layer.

In some aspects, the thin film transistor substrate further comprises: an etch stopper layer disposed between the source electrode and the drain electrode on the second oxide semiconductor layer.

In some aspects, the etch stopper layer has a smaller size than the second oxide semiconductor layer.

In some aspects, the etch stopper layer has same size with the second oxide semiconductor layer.

In some aspects, the thin film transistor substrate further comprises: a gate insulating layer on the second oxide semiconductor layer; a gate electrode overlapped with a middle portion of the second oxide semiconductor layer on the gate insulating layer; an intermediate insulating layer on the gate electrode; and a source electrode and a drain electrode formed on the intermediate insulating layer, wherein the first oxide semiconductor layer has the second composition ratio and the second oxide semiconductor layer has the first composition ratio, wherein the first oxide semiconductor layer has same size with the second oxide semiconductor layer, wherein the source electrode contacts one portion of the second oxide semiconductor layer via a source contact hole penetrating the intermediate insulating layer, and wherein the drain electrode contacts another portion of the second oxide semiconductor layer via a drain contact hole penetrating the intermediate insulating layer.

In some aspects, the gate insulating layer covers the whole surface of the substrate, and the source contact hole and the drain contact hole further penetrate the gate insulating layer.

In some aspects, the one layer having the first composition ratio has a first thickness, the other layer having the second composition ratio has a second thickness, and the second thickness is equal to or higher than ⅕ of the first thickness.

In some aspects, the thin film transistor substrate further comprises: a gate insulating layer disposed at any one of upper layer and lower layer of the oxide semiconductor layer; and a gate electrode overlapped with the oxide semiconductor layer with the gate insulating layer there-between, wherein any one layer of the first oxide semiconductor layer and the second oxide semiconductor layer being closer to the gate electrode has the first composition ratio, and wherein other layer being far from the gate electrode has the second composition ratio.

The thin film transistor substrate for a flat panel display includes an oxide semiconductor layer having two different type oxide layers. Especially, the upper oxide semiconductor layer at upper layer has different composition ratio from the lower oxide semiconductor layer. As the upper oxide semiconductor layer has higher resistivity than the lower oxide semiconductor layer, the threshold voltage is not changed under the short channel length structure. As the high speed operation can be ensured by the short channel length structure and the stable threshold voltage can be acquired, the present disclosure provides the superior thin film transistor substrate having the stable characteristics under the positive bias stress and/or negative bias stress. The thin film transistor substrate according to the present disclosure provides an ultra high density and large area flat panel display having the superior video quality.

### BRIEF DESCRIPTION OF THE DRAWINGS

The accompanying drawings, which are included to provide a further understanding of the present disclosure and are incorporated in and constitute a part of this application, illustrate aspects of the disclosure and together with the description serve to explain the principles of the disclosure.

In the drawings:

FIG. 1 is a plan view illustrating a thin film transistor substrate having an oxide semiconductor layer of the fringe field type liquid crystal display according to the related art;

FIG. 2 is a cross sectional view illustrating the thin film transistor substrate along cutting line I-I′ in FIG. 1;

FIG. 3 is a plan view illustrating a structure of a pixel in an active matrix organic light emitting diode display according to the related art;

FIG. 4 is a cross sectional view illustrating the structure of the active matrix organic light emitting diode display along cutting line II-II′ in FIG. 3;

FIG. 5 is a cross sectional view illustrating a structure of a thin film transistor substrate including an oxide semiconductor material according to an aspect of the present disclosure;

FIG. 6 is a cross sectional view illustrating a structure of a thin film transistor substrate including an oxide semiconductor material according to another aspect of the present disclosure;

FIG. 7 is a cross sectional view illustrating a structure of a thin film transistor substrate including an oxide semiconductor material according to yet another aspect of the present disclosure; and

FIG. 8 is a cross sectional view illustrating a structure of a thin film transistor substrate including an oxide semiconductor material according to a further aspect of the present disclosure.

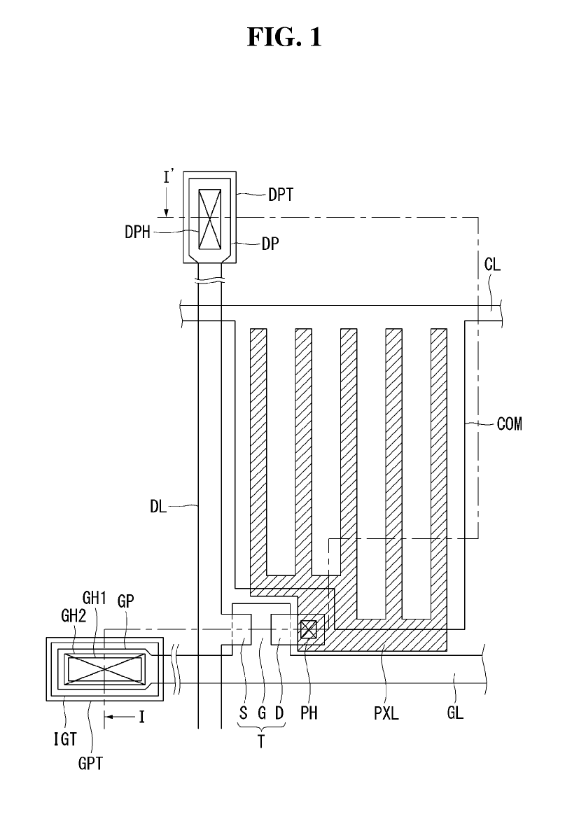

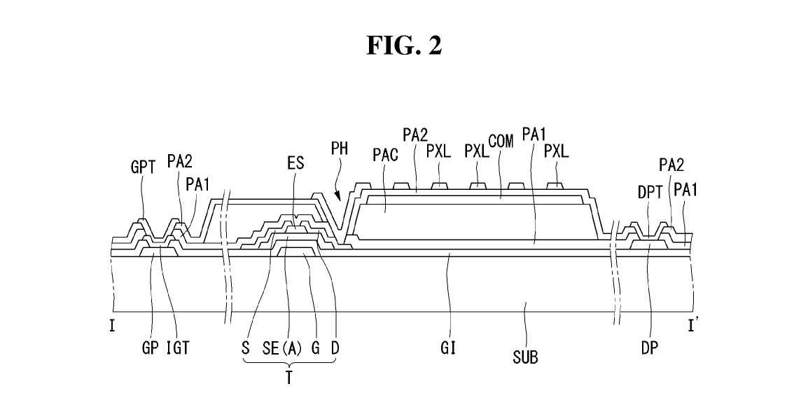

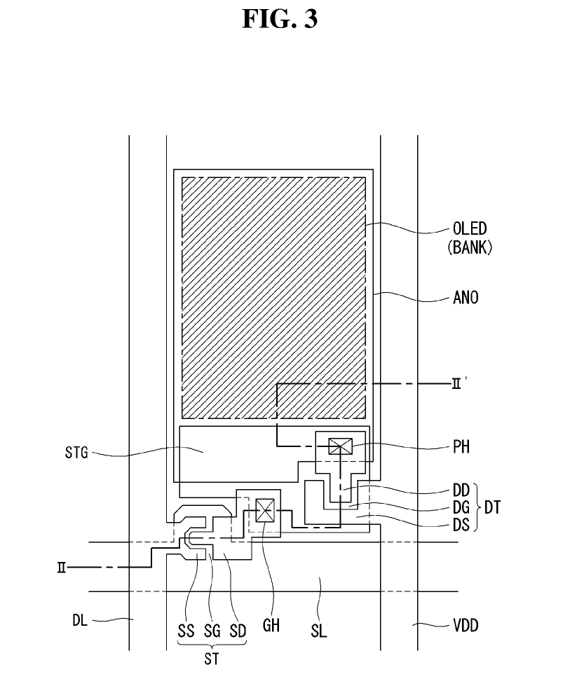

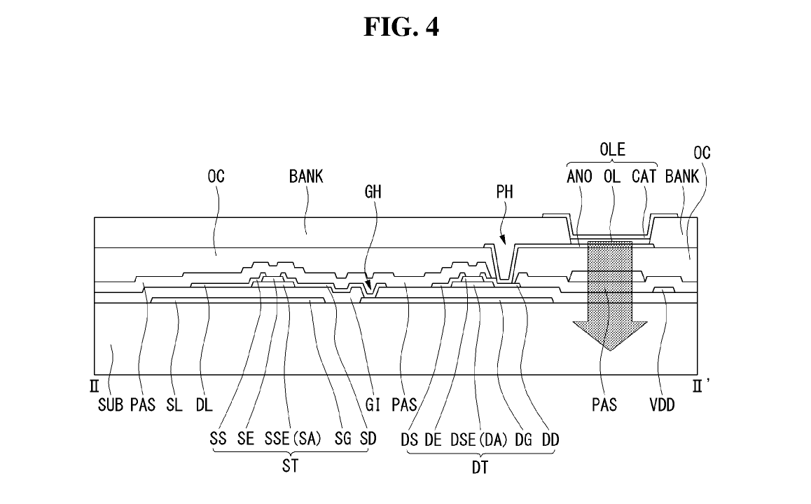

### DETAILED DESCRIPTION

Referring to attached figures, preferred aspects of the present disclosure will be described. Like reference numerals designate like elements throughout the detailed description. However, the present disclosure is not restricted by these aspects but can be applied to various changes or modifications without changing the technical spirit. In the following aspects, the names of the elements are selected for ease of explanation and may be different from actual names.

Hereinafter, we will explain about various structures of a thin film transistor substrate for a flat panel display. Specifically, we will explain as focusing on the structures of a thin film transistor. Applying the thin film transistor substrate including the thin film transistor according to the present disclosure to a display, we can get a flat panel display having the superior video quality.

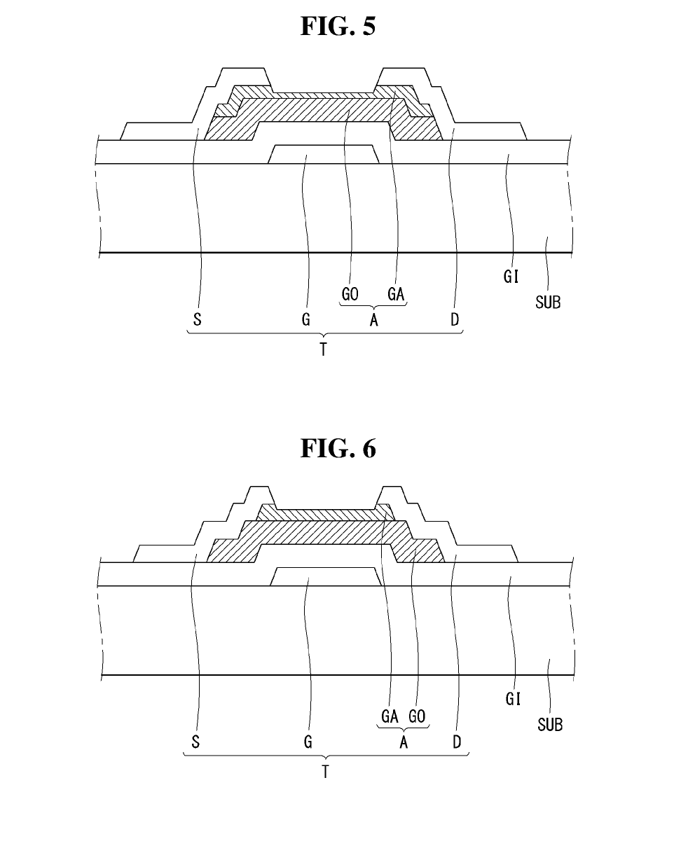

FIG. 5 is a cross sectional view illustrating a structure of a thin film transistor substrate including an oxide semiconductor material according to an aspect of the present disclosure. Referring to FIG. 5, a thin film transistor substrate according to an aspect of the present disclosure comprises a plurality of pixel areas including at least one thin film transistor T in each pixel area, disposed in a matrix manner on a substrate SUB. Here, for convenience's sake, the structure of the thin film transistor T will be described herein.

On the substrate SUB, a gate electrode G is formed. A gate insulating layer GI is formed on the gate electrode G and covers the entire surface of the substrate SUB. On the gate insulating layer GI, a semiconductor layer A is formed and overlaps a middle portion of the gate electrode G. The semiconductor layer A has a stack structure in which a first oxide semiconductor layer GO and a second oxide semiconductor layer GA are sequentially stacked so that a bi-layer semiconductor is formed. The first oxide semiconductor layer GO and the second oxide semiconductor layer GA may have the same shape and the same size with each other. On the second oxide semiconductor layer GA, a source electrode S and a drain electrode D are disposed to be apart and face each other with a predetermined distance. That is, the source electrode S contacts on one upper surface of the second semiconductor layer GA, and the drain electrode D contacts on another upper surface of the second semiconductor layer GA.

Here, the first oxide semiconductor layer GO may include a metal oxide material such as an indium-gallium-zinc oxide (or IGZO) material having a thickness of about 500 Å. A composition ratio of indium, gallium and zinc may be 1:1:1.

The second oxide semiconductor layer GA may include a metal oxide material such as an indium-gallium-zinc oxide (or IGZO) material having a thickness of about 300 Å. A ratio amount of the gallium is larger than others. For example, a value of Zn/Ga may be equal or larger than 0 (zero) and less than 0.5. Further, the value of Ga/In may be larger than 1.

In order to acquire enhanced characteristics for the oxide semiconductor material, a new structure of the oxide semiconductor layer is developed and disclosed in the present disclosure as follows. Firstly, varying the composition ratio of the second semiconductor layer GA stacked on the first oxide semiconductor layer GO, the characteristics of the bi-layer oxide semiconductor were evaluated. The characteristics is detected by measuring the threshold voltages with 10 μm (micrometer) of channel length and 4 μm (micrometer) of channel length. Then, by calculating difference between the two threshold voltages, a degrading amount of the characteristics can be evaluated.

Table 1 shows the channel length variation, the differences between the threshold voltage of the 10 μm channel length and the threshold voltage of the 4 μm channel length, according to the various composition ratios of the indium-gallium-zinc oxide material,

TABLE 1

| Zn/Ga | | 0 | 0.45 | 0.5 | 1.0 |
|---|---|---|---|---|---|
| Composition ratio of the 2^{nd} | No | 1:2:0 | 1:2:0.9 | 1:2:1 | 1:2:2 |
| oxide semiconductor layer | | | | | |
| Composition ratio of the 1^{st} | 1:1:1 | | | | |
| oxide semiconductor layer | | | | | |
| CLV (Vth10-Vth4) | 4.47 | 0.5 | 0.56 | 1.99 | 6.02 |

Here, ‘No’ means that the second oxide semiconductor layer GA was not formed, that is, the semiconductor layer include only the first oxide semiconductor layer GO. CLV(Vth10-Vth4) means the channel length variation which is the difference between the threshold voltage of the 10 μm channel length and the threshold voltage of the 4 μm channel length. The content unit of the composition ratio may be represented with the atomic weight, the molecular weight or the mole number. Here, the unit of content is not used because the composition ratio may be more important than the content of each element.

When the difference of the threshold voltages between 10 μm and 4 μm is too large, the threshold voltage was more easily degraded as the channel length is getting shorter, so that the characteristics of the thin film transistor were not be stable. On the other hand, when the difference of the threshold voltages between 10 μm and 4 μm is small, the threshold is not varied with a short channel structure, so that the characteristics of the thin film transistor were stable for a long time usage. Applying the thin film transistor including the bi-layer oxide semiconductor to the flat panel display, the present disclosure provides a large area and ultra high density display having a superior video quality.

According to Table 1, for the cases that the component ratio of Ga:Zn is equal to or higher than 2:0 and is less than 2:1, the channel length variation is less than 1 voltage. This means that the characteristics of the thin film transistor of which channel length is 4 μm is the same as that of the thin film transistor of which channel length is 10 μm. The composition ratio of zinc and gallium, the value of Zn (zinc)/Ga (gallium) may be less than 0.5. For composition ratio of all elements, the ratio of In:Ga:Zn for the first oxide semiconductor layer GO may be 1:1:1, and the ratio of In:Ga:Zn for the second oxide semiconductor layer GA may be selected from 1:2:0 to 1:2:0.9.

Further, the source electrode S and the drain electrode D directly contact on the top surface of the second oxide semiconductor layer GA. When patterning the source electrode S and the drain electrode D, a portion of thickness of the second semiconductor layer GA exposed between the source electrode S and the drain electrode D may be etched out. The structure having the etched channel layer may be referred to as a back-channel-etch structure. As the first oxide semiconductor layer GO, the main channel layer, is not etched or damaged, the characteristics of the channel area is not affected or changed.

As described above, the thin film transistor according to an aspect of the present disclosure has a short channel length and a stable threshold voltage by having a bi-layer oxide semiconductor in which the second oxide semiconductor layer GA is stacked on the first oxide semiconductor layer GO. Further, the second oxide semiconductor layer GA functions to protect the first oxide semiconductor layer GO.

With the bi-layer oxide semiconductor according to an aspect, due to the short channel length with the stable threshold voltage, it is suitable for a large area flat panel display. However, in an aspect of the present disclosure, the source electrode S and the drain electrode D directly contact on the second oxide semiconductor layer GA. As to the electrical characteristics, the resistivity of the second oxide semiconductor layer GA is larger than that of the first oxide semiconductor layer GO. That is, the thin film transistor having the bi-layer oxide semiconductor has a larger resistivity and work function than those of the thin film transistor having a single layer oxide semiconductor.

As the thin film transistor having the bi-layer oxide semiconductor has the larger resistivity, the contact resistance between the second oxide semiconductor layer GA and the source electrode S and/or between the second oxide semiconductor layer GA and the drain electrode D may be increased. In an aspect of the present disclosure, the short channel length can be obtained with the bi-layer oxide semiconductor, but the contact resistance between the oxide semiconductor layer and the metal layer may have the higher value than that of the single layer oxide semiconductor.

FIG. 6 is a cross sectional view illustrating a structure of a thin film transistor substrate including an oxide semiconductor material according to another aspect of the present disclosure.

In another aspect of the present disclosure, a structure of a thin film transistor having the bi-layer oxide semiconductor in which the contact resistance between the oxide semiconductor layer and the source-drain metal layer is maintained in low value. Referring to FIG. 6, the thin film transistor substrate according to another aspect comprises a plurality of thin film transistors T arrayed in a matrix manner on a substrate SUB.

On the substrate SUB, a gate electrode G is formed. A gate insulating layer GI is deposited on the gate electrode G and covers the entire surface of the substrate SUB. On the gate insulating layer GI, a semiconductor layer A is formed and overlaps a middle portion of the gate electrode G. The semiconductor layer A has a stack structure in which a first oxide semiconductor layer GO and a second oxide semiconductor layer GA are sequentially stacked so that a bi-layer semiconductor is formed.

Specifically, the second oxide semiconductor layer GA has smaller size (e.g., length and thickness) than the first oxide semiconductor layer GO. Further, the second oxide semiconductor layer GA is disposed on the middle portion of the first oxide semiconductor layer GO without covering side portions.

As a result, the source electrode S and the drain electrode D disposed on the second oxide semiconductor layer GA contact portions of the upper surface of the second oxide semiconductor layer GA and portions of the upper surface of the first oxide semiconductor layer GO. The source electrode S and the drain electrode D are facing each other with a predetermined distance. That is, the source electrode S contacts with one upper surface of the second semiconductor layer GA and one upper surface of the first semiconductor layer GO. In addition, the drain electrode D contacts with another upper surface of the second semiconductor layer GA and another upper surface of the first semiconductor layer GO.

The composition ratios of the first semiconductor layer GO and the second semiconductor layer GA according to another aspect may be the same as those of the previously described aspect of the disclosure. On the other hands, the oxide semiconductor layer according to another aspect has the first semiconductor layer GO having lower resistivity than that of the second semiconductor layer GA directly contacts the source electrode S and the drain electrode D. Therefore, the contact resistance between the semiconductor layer and the metal layer including the source electrode S and the drain electrode D can be maintained in a low value.

In the previously described aspects, the source electrode S and the drain electrode D are directly formed and contacted on the semiconductor layer A. Therefore, the thin film transistor has a back-channel-etch structure in which the thickness of the channel layer defined between the source electrode S and the drain electrode D of the semiconductor layer A is etched out. In addition, in previously disclosed aspects, only the second oxide semiconductor layer GA is etched out but the first oxide semiconductor layer GO is intact. Therefore, the characteristics of the channel is not affected or degraded by the back-channel-etch structure. However, for the large area display panel in which vast number of transistors is disposed on large area substrate, it is very hard to form all transistors to have the same or similar condition and/or size over all area of the substrate.

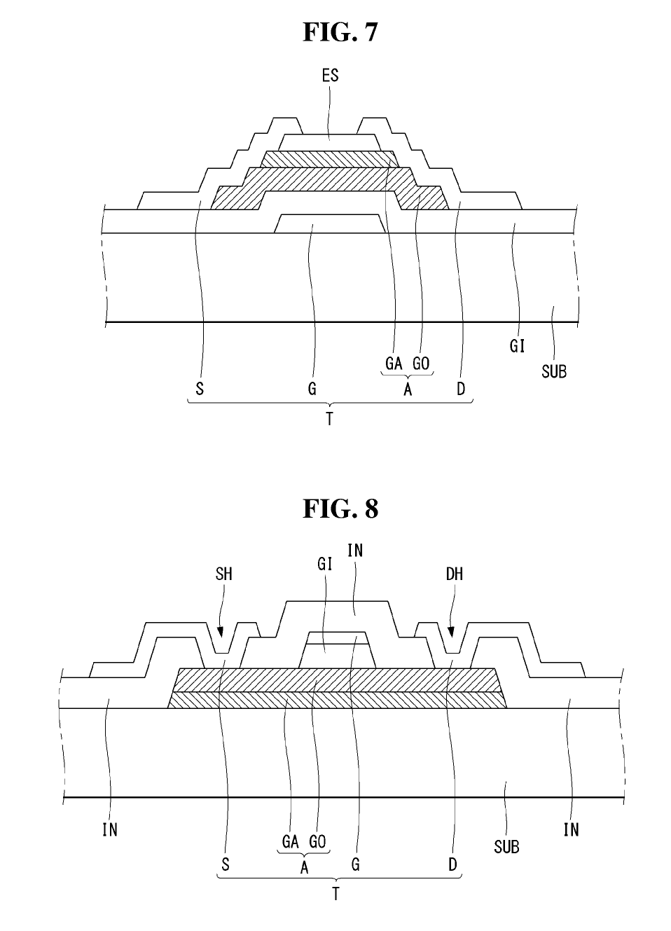

In yet another aspect, the thin film transistor has an etch stopper for protecting the oxide semiconductor layer from being etched. FIG. 7 is a cross sectional view illustrating a structure of a thin film transistor substrate including an oxide semiconductor material according to yet another aspect of the present disclosure.

Referring to FIG. 7, the thin film transistor substrate according to yet another aspect of the present disclosure comprises a plurality of thin film transistors T arrayed in a matrix manner on a substrate SUB. On the substrate SUB, a gate electrode G is formed. A gate insulating layer GI is deposited on the gate electrode G and covers the entire surface of the substrate SUB. On the gate insulating layer GI, a semiconductor layer A is formed and overlaps a middle portion of the gate electrode G. The semiconductor layer A has a stack structure in which a first oxide semiconductor layer GO and a second oxide semiconductor layer GA are sequentially stacked so that a bi-layer semiconductor is formed.

Specifically, the second oxide semiconductor layer GA has smaller size (e.g., length) than that of the first oxide semiconductor layer GO. Further, the second oxide semiconductor layer GA is disposed at the middle portion of the first oxide semiconductor layer GO not covering circumferential portions.

On the second oxide semiconductor layer GA, an etch stopper layer ES is formed. The etch stopper layer ES may be formed and covers the middle portion of the second oxide semiconductor layer GA. On the etch stopper layer ES, the source electrode S and the drain electrode D may be formed.

The source electrode S and the drain electrode D disposed on the etch stopper layer ES directly contact with portions of the upper surfaces of the etch stopper layer ES, portions of the upper surfaces of the second oxide semiconductor layer GA and portions of the upper surfaces of the first oxide semiconductor layer GO. The source electrode S and the drain electrode D face each other with a predetermined distance. That is, the source electrode S directly contacts with one upper surface of the etch stopper layer ES, one upper surface of the second oxide semiconductor layer GA and one upper surface of the first oxide semiconductor layer GO. The drain electrode D directly contacts with another upper surface of the etch stopper layer ES, another upper surface of the second oxide semiconductor layer GA and another upper surface of the first oxide semiconductor layer GO.

For another example even though not shown in figures, the etch stopper layer SE may have the same size as the second oxide semiconductor layer GA. In this case, the source electrode S and the drain electrode D directly contact with portions of the upper surface of the etch stopper layer SE and portions of the upper surface of the first oxide semiconductor layer GO. The source electrode S and the drain electrode D are facing each other with a predetermined distance. That is, the source electrode S contacts with one upper surface of the etch stopper layer SE and one upper surface of the first semiconductor layer GO. In addition, the drain electrode D contacts with another upper surface of the etch stopper layer ES and another upper surface of the first semiconductor layer GO.

The composition ratios of the first semiconductor layer GO and the second semiconductor layer GA according to yet another aspect may be the same as those of the previously described aspect. On the other hands, the oxide semiconductor layer according to yet another aspect has the first semiconductor layer GO having lower resistivity than that of the second semiconductor layer GA directly contacts the source electrode S and the drain electrode D. Therefore, the contact resistance between the semiconductor layer and the metal layer including the source electrode S and the drain electrode D can be maintained in a low value.

In the previous three aspects, a bottom gate structure thin film transistor was disclosed and described. In still another aspect, referring to FIG. 8, a top gate structure thin film transistor will be disclosed and described herein. FIG. 8 is a cross sectional view illustrating a structure of a thin film transistor substrate including an oxide semiconductor material according to still another aspect of the present disclosure.

Referring to FIG. 8, the thin film transistor substrate according to still another aspect of the present disclosure comprises a plurality of thin film transistors T arrayed in a matrix manner on a substrate SUB. On the substrate SUB, an oxide semiconductor layer A is formed. Even not shown in FIG. 8, a buffer layer may be firstly deposited on the substrate SUB under the oxide semiconductor layer A.

For the case of the top gate structure, the oxide semiconductor layer A may have a different stack structure from that of the bottom gate structure. For example, the first oxide semiconductor layer GO may be stacked on the second oxide semiconductor layer GA. Even though the stacking order is different from the aspect shown in FIG. 5, the composition ratios of the first semiconductor layer GO and the second semiconductor layer GA according to still another aspect may be same with those of the aspect shown in FIG. 5.

On the oxide semiconductor layer A, the gate electrode G is disposed on the middle of the oxide semiconductor layer A with the gate insulating layer GI there-between. The gate insulating layer GI and the gate electrode G may have the same shape and size on the middle portion of the oxide semiconductor layer A. The intermediate insulating layer IN is deposited on the gate electrode G and covers the entire surface of the substrate SUB.

On the intermediate insulating layer IN, the source electrode S and the drain electrode D are formed and face each other with a predetermined distance. The source electrode S contacts one upper surface of the first oxide semiconductor layer GO via a source contact hole SH penetrating the intermediate insulating layer IN. In addition, the drain electrode D contacts another upper surface of the first oxide semiconductor layer GO via a drain contact hole DH penetrating the intermediate insulating layer IN.

For the top gate structure, the gate electrode G is disposed over the oxide semiconductor layer A. The gate electrode G provides an electric field to the oxide semiconductor layer A so that the oxide semiconductor layer A forms a channel. The layer forming the channel in the oxide semiconductor layer A is the first oxide semiconductor layer GO having the composition ratio of Indium:Gallium:Zinc is 1:1:1, the first composition ratio. The second oxide semiconductor layer GA having the composition ratio of Indium:Gallium:Zinc may be 1:2:0 to 1:2:0.5, the second composition ratio, and the second oxide semiconductor layer GA is an auxiliary layer for enhancing the band gap of the oxide semiconductor layer A. Therefore, the second oxide semiconductor layer GA preferably has higher resistivity than that of the first oxide semiconductor layer GO and is to increase the work function of the oxide semiconductor layer A.

The first oxide semiconductor layer GO for forming the channel area may be disposed to be close to the gate electrode G. For the top gate structure, the second oxide semiconductor layer GA may be disposed at the lower layer and the first semiconductor layer GO is disposed at the upper layer. On the other hands, for the bottom gate structure, as explained in the first to third aspects, the first oxide semiconductor layer GO may be disposed at the lower layer so as to be close to the gate electrode G.

Further, even though shown in FIG. 8, the gate insulating layer GI may not cover the entire surface of the substrate SUB, but cover only the middle portion of the oxide semiconductor layer A under the gate electrode G as having the same size as the gate electrode G. In this case, the source contact hole SH and the drain contact hole DH may be formed by penetrating the intermediate insulating layer IN only.

As described above, various examples for the thin film transistor substrate having the bi-layer oxide semiconductor in which the first oxide semiconductor layer GO and the second oxide semiconductor layer GA are stacked were disclosed herein. In a further aspect of the present disclosure various features on the thickness for the first oxide semiconductor layer GO and the second oxide semiconductor layer GA will be disclosed. The thickness features disclosed in the various previously described aspects can be applied in a further aspect of the present disclosure.

In the previously described aspect, the first oxide semiconductor layer GO has the thickness of 500 Å, and the second oxide semiconductor layer GA has the thickness of 300 Å. However, the thickness condition may not be restricted with these values. The second oxide semiconductor layer GA may have a thinner thickness than the first oxide semiconductor layer GO. Further, the thickness of the second oxide semiconductor layer GA may be larger than ⅕ of the thickness of the first oxide semiconductor layer GO. That is, the thickness of the second oxide semiconductor layer may be selected within a desired range.

For example, in the previously described aspects, the thin film transistor T has a back-channel-etch (BCE) structure in which the thickness of the second oxide semiconductor layer GA is etched out. Here, the thinned (or remained) thickness of the second oxide semiconductor layer may be ⅕ of the first oxide semiconductor layer GO at least. To do so, the initial thickness of the second oxide semiconductor layer GA may be ⅖ of the first oxide semiconductor layer GO at least.

In the previously described aspect, the second oxide semiconductor layer GA is not etched because it is protected by the etch stopper layer ES. Therefore, the second oxide semiconductor layer GA may be ⅕ of the first oxide semiconductor layer GO. The second oxide semiconductor layer GA may have any thickness less than the thickness of the first oxide semiconductor layer GO and thicker than ⅕ of the first oxide semiconductor layer GO.

The second oxide semiconductor layer GA may be stacked on the first oxide semiconductor layer GO. In this case, portions of the second oxide semiconductor layer GA are removed to expose one portion of the first oxide semiconductor layer GO and another portion of the first oxide semiconductor layer GO for contacting the source electrode S and drain electrode D with the first oxide semiconductor layer. When patterning the second oxide semiconductor layer GA, the thickness of the second oxide semiconductor layer GA may be as thin as possible for shorting the patterning process tact time. Therefore, the second oxide semiconductor layer GA may be ⅕ of the first oxide semiconductor layer GO. The second oxide semiconductor layer GA may have any thickness less than the thickness of the first oxide semiconductor layer GO and thicker than ⅕ of the first oxide semiconductor layer GO.

While the aspect of the present disclosure has been described in detail with reference to the drawings, it will be understood by those skilled in the art that the disclosure can be implemented in other specific forms without changing the technical spirit or essential features of the disclosure. Therefore, it should be noted that the forgoing aspects are merely illustrative in all aspects and are not to be construed as limiting the disclosure. The scope of the disclosure is defined by the appended claims rather than the detailed description of the disclosure. All changes or modifications or their equivalents made within the meanings and scope of the claims should be construed as falling within the scope of the disclosure.

What is claimed is:

1. A thin film transistor substrate, comprising:
a substrate; and
an oxide semiconductor layer on or above the substrate and including a first oxide semiconductor and a second oxide semiconductor layer on the first oxide semiconductor layer,
wherein one of the first and second oxide semiconductor layers has a first composition ratio of indium, gallium and zinc to be 1:1:1, and the other of the first and second oxide semiconductor layers has a second composition ratio of indium, gallium and zinc and an indium ratio being higher than a zinc ratio.

2. The thin film transistor substrate according to the claim 1, wherein the zinc ratio to an gallium ratio in the second composition ratio is equal to or higher than zero and lower than 0.5.

3. The thin film transistor substrate according to the claim 2, wherein the gallium ratio to the indium ratio in the second composition ratio is higher than 1.

4. The thin film transistor substrate according to the claim 1, wherein the second composition ratio of the indium, gallium and zinc is in a range of 1:2:0 to 1:2:0.9.

5. The thin film transistor substrate according to the claim 1, further comprising:
a gate electrode vertically overlapping the oxide semiconductor layer with a gate insulating layer there-between under the first oxide semiconductor layer;
a source electrode contacting a first portion of an upper surface of the first oxide semiconductor layer; and
a drain electrode contacting a second portion of the upper surface of the first oxide semiconductor layer,
wherein the first oxide semiconductor layer has the first composition ratio and the second oxide semiconductor layer has the second composition ratio.

6. The thin film transistor substrate according to the claim 5, wherein the second oxide semiconductor layer has a smaller area than the first oxide semiconductor layer, and is disposed on a middle portion of the first oxide semiconductor layer.

7. The thin film transistor substrate according to the claim 6, wherein the source electrode contacts a first portion of an upper surface of the second oxide semiconductor layer; and the drain electrode contacts a second portion of the upper surface of the second oxide semiconductor layer.

8. The thin film transistor substrate according to the claim 6, further comprising
an etch stopper layer disposed between the source electrode and the drain electrode on the second oxide semiconductor layer.

9. The thin film transistor substrate according to the claim 8, wherein the etch stopper layer has a smaller length than the second oxide semiconductor layer.

10. The thin film transistor substrate according to the claim 8, wherein the etch stopper layer has a same length as the second oxide semiconductor layer.

11. The thin film transistor substrate according to the claim 1, further comprising:
a gate insulating layer on the second oxide semiconductor layer;
a gate electrode on the gate insulating layer and vertically overlapping a middle portion of the second oxide semiconductor layer;
an intermediate insulating layer on the gate electrode; and
a source electrode and a drain electrode on the intermediate insulating layer,
wherein the first oxide semiconductor layer has the second composition ratio and the second oxide semiconductor layer has the first composition ratio,
wherein the first oxide semiconductor layer has substantially a same length as the second oxide semiconductor layer,
wherein the source electrode contacts a first portion of the second oxide semiconductor layer via a source contact hole penetrating into the intermediate insulating layer, and
wherein the drain electrode contacts a second portion of the second oxide semiconductor layer via a drain contact hole penetrating into the intermediate insulating layer.

12. The thin film transistor substrate according to the claim 11, wherein the gate insulating layer covers an entire surface of the substrate, and the source contact hole and the drain contact hole penetrate into the gate insulating layer.

13. The thin film transistor substrate according to the claim 1,
wherein the one of the first and second oxide semiconductor layers having the first composition ratio has a first thickness, the other of the first and second oxide semiconductor layers having the second composition ratio has a second thickness, and
wherein the second thickness is equal to or greater than ⅕ of the first thickness.

14. The thin film transistor substrate according to the claim 1, further comprising:
a gate insulating layer disposed on one of the first and second oxide semiconductor layers; and
a gate electrode vertically overlapping the oxide semiconductor layer with the gate insulating layer there-between,
wherein one of the first and second oxide semiconductor layers closer to the gate electrode has the first composition ratio, and
the other of the first and second oxide semiconductor layers far from the gate electrode has the second composition ratio.

15. A thin film transistor substrate for a display device, comprising:
a substrate;
a first oxide semiconductor layer on or over the substrate;
a second oxide semiconductor layer on the first oxide semiconductor layer,
wherein the first and second oxide semiconductor layers include indium, gallium and zinc and have different composition ratios in indium, gallium and zinc, the first oxide semiconductor layer has a higher resistivity than the second oxide semiconductor layer, and a threshold voltage of the display device changes less than 1.0 voltage when a channel length is reduced.

16. The thin film transistor substrate according to claim 15, wherein the first oxide semiconductor layer has a first composition of indium, gallium and zinc of 1:1:1 and the second oxide semiconductor layer has a second composition ratio of an indium ratio higher than a zinc ratio.

17. The thin film transistor substrate according to the claim 15, wherein the zinc ratio to a gallium ratio in the second composition ratio is equal to or higher than zero and lower than 0.5.

18. The thin film transistor substrate according to the claim 17, wherein the indium ratio to the gallium ratio in the second composition ratio is higher than 1.

19. The thin film transistor substrate according to the claim 15, wherein the second composition ratio of indium, gallium and zinc is in a range of 1:2:0 to 1:2:0.9.

20. The thin film transistor substrate according to the claim 15, wherein the channel length is reduced from about 10 μm to about 4 μm.

21. A thin film transistor substrate for a display device, comprising:
a substrate;
a first oxide semiconductor layer on the substrate;
a second oxide semiconductor layer on the first oxide semiconductor layer, wherein the first and second oxide semiconductor layers include indium, gallium and zinc and have different composition ratios in indium, gallium and zinc, the first oxide semiconductor layer a lower resistivity than the second oxide semiconductor layer, and a threshold voltage of the display device changes less than 1.0 voltage when a channel length is reduced;
a gate insulating layer on the second oxide semiconductor layer;
a gate electrode on the gate insulating layer and vertically overlapping a middle portion of the second oxide semiconductor layer;
an intermediate insulating layer on the gate electrode; and
a source electrode and a drain electrode on the intermediate insulating layer, wherein the source electrode contacts a first portion of the second oxide semiconductor layer through a source contact hole, and the drain electrode contacts a second portion of the second oxide semiconductor layer through a drain contact hole.

22. The thin film transistor substrate according to claim 21, wherein the second oxide semiconductor layer has a first composition of indium, gallium and zinc of 1:1:1 and the first oxide semiconductor layer has a second composition ratio of an indium ratio higher than a zinc ratio.

23. The thin film transistor substrate according to the claim 21, wherein the zinc ratio to a gallium ratio in the second composition ratio is equal to or higher than zero and lower than 0.5.

24. The thin film transistor substrate according to the claim 17, wherein the indium ratio to the gallium ratio in the second composition ratio is higher than 1.

25. The thin film transistor substrate according to the claim 21, wherein the second composition ratio of indium, gallium and zinc is in a range of 1:2:0 to 1:2:0.9.

26. The thin film transistor substrate according to the claim 15, wherein the channel length is reduced from about 10 μm to about 4 μm.
